(19) United States
(12) Patent Application Publication
(10) Pub. No.: US 2020/0103752 A1
(43) Pub. Date: Apr. 2, 2020

(54) PHOTOSENSITIVE RESIN COMPOSITION, PHOTOSENSITIVE RESIN LAYER AND ELECTRONIC DEVICE USING THE SAME

(71) Applicant: SAMSUNG SDI CO., LTD., Yongin-si (KR)

(72) Inventors: Jiyun KWON, Suwon-si (KR); Jinhee KANG, Suwon-si (KR); Do-Uk KIM, Suwon-si (KR); Chang-Hyun KWON, Suwon-si (KR); Sang Soo KIM, Suwon-si (KR); Ieju KIM, Suwon-si (KR); Taek-Jin BAEK, Suwon-si (KR)

(21) Appl. No.: 16/567,121

(22) Filed: Sep. 11, 2019

(30) Foreign Application Priority Data
Sep. 28, 2018 (KR) 10-2018-0116411

(51) Int. Cl. G03F 7/022; G03F 7/004; C08L 61/06; C08L 79/08; G03F 7/039; C08L 45/00

(52) U.S. Cl. CPC G03F 7/022; G03F 7/0045; C08L 61/06; C08L 79/08; C08K 5/3445; C08L 45/00; C08L 2312/00; C08L 2203/20; G03F 7/0392

(57) ABSTRACT

A positive photosensitive resin composition, a photosensitive resin layer, and an electronic device, the composition including an alkali soluble resin; a photosensitive diazoquinone compound; a dissolution controlling agent represented by Chemical Formula 1; a cross-linking agent represented by Chemical Formula 2; and a solvent, wherein the dissolution controlling agent and the cross-linking agent are included in a weight ratio of about 1:1 to about 1:2:

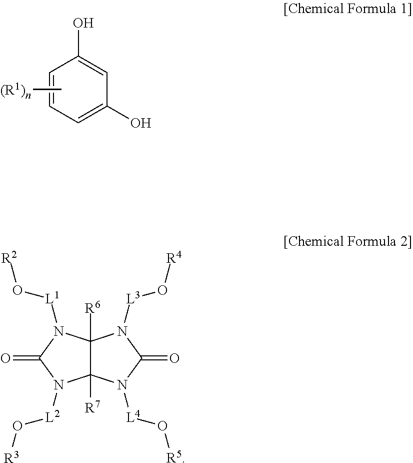

### CROSS-REFERENCE TO RELATED APPLICATION

Korean Patent Application No. 10-2018-0116411, filed on Sep. 28, 2018, in the Korean Intellectual Property Office, and entitled: “Photosensitive Resin Composition, Photosensitive Resin Layer and Electronic Device Using the Same,” is incorporated by reference herein in its entirety.

### BACKGROUND

### 1. Field

This disclosure relates to a photosensitive resin composition, and a photosensitive resin layer and an electronic device including the same.

### 2. Description of the Related Art

A polyimide resin, a polybenzoxazole resin, and the like having improved heat resistance, electrical characteristics, and mechanical characteristics, may be used for a surface protective layer and an interlayer insulating layer used in materials for display device panels and semiconductor devices. These resins may have low solubility in various solvents, and may be provided as a composition in which precursors thereof are dissolved in a solvent.

### SUMMARY

The embodiments may be realized by providing a positive photosensitive resin composition including an alkali soluble resin; a photosensitive diazoquinone compound; a dissolution controlling agent represented by Chemical Formula 1; a cross-linking agent represented by Chemical Formula 2; and a solvent, wherein the dissolution controlling agent and the cross-linking agent are included in a weight ratio of about 1:1 to about 1:2:

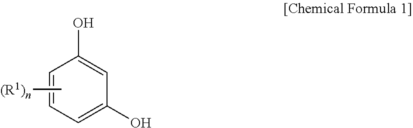

wherein in Chemical Formula 1, R¹ is a substituted or unsubstituted C1 to C20 alkyl group, and n is an integer of 0 or 1,

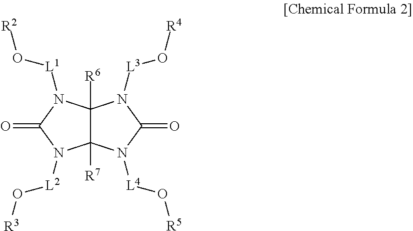

wherein in Chemical Formula 2, R² to R⁷ are each independently a hydrogen atom or a substituted or unsubstituted C1 to C20 alkyl group, and L¹ to L⁴ are each independently a substituted or unsubstituted C1 to C20 alkylene group.

The dissolution controlling agent represented by Chemical Formula 1 may be represented by Chemical Formula 1-1 or Chemical Formula 1-2:

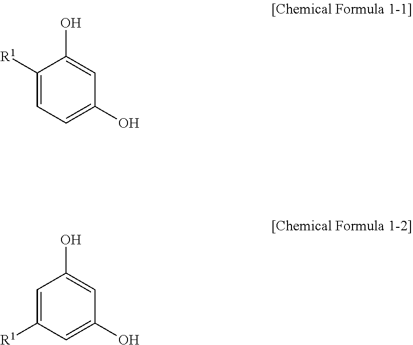

wherein, in Chemical Formula 1-1 and Chemical Formula 1-2, R¹ may be a substituted or unsubstituted C1 to C20 alkyl group.

R¹ may be an unsubstituted C1 to C6 alkyl group.

The dissolution controlling agent represented by Chemical Formula 1 may be represented by one of Chemical Formula 1A to Chemical Formula 1E:

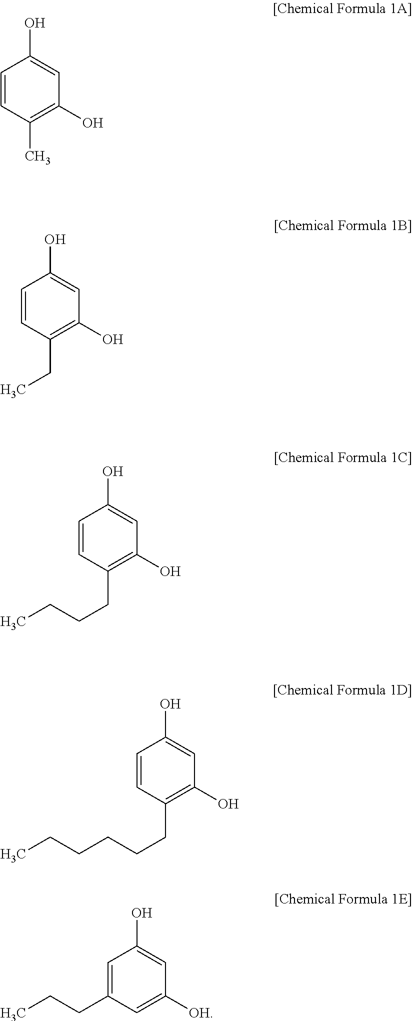

In Chemical Formula 2, R² to R⁵ may each independently be a substituted or unsubstituted C1 to C20 alkyl group, and R⁶ and R⁷ may each be a hydrogen atom.

The alkali soluble resin may include a polybenzoxazole precursor, a polyimide precursor, a novolac resin, or a combination thereof.

The photosensitive resin composition may include, based on 100 parts by weight of the alkali soluble resin about 1 part by weight to about 100 parts by weight of the photosensitive diazoquinone compound, about 10 parts by weight to about 30 parts by weight of the dissolution controlling agent, about 10 parts by weight to about 60 parts by weight of the cross-linking agent, and about 100 parts by weight to about 500 parts by weight by weight of the solvent.

The positive photosensitive resin may further include a diacid, an alkanol amine, a leveling agent, a silane coupling agent, a surfactant, an epoxy compound, a radical polymerization initiator, a thermal latent acid generator, or a combination thereof.

The embodiments may be realized by providing a photosensitive resin layer formed from the photosensitive resin composition according to an embodiment.

The embodiments may be realized by providing an electronic device including the photosensitive resin layer according to an embodiment.

### DETAILED DESCRIPTION

Example embodiments will now be described more fully hereinafter; however, they may be embodied in different forms and should not be construed as limited to the embodiments set forth herein. Rather, these embodiments are provided so that this disclosure will be thorough and complete, and will fully convey exemplary implementations to those skilled in the art.

It will also be understood that when a layer or element is referred to as being “on” another layer or element, it can be directly on the other layer or element, or intervening layers may also be present. As used herein, the term “or” is not an exclusive term, e.g., “A or B” includes A, B, or A and B.

As used herein, when specific definition is not otherwise provided, “alkyl group” may refer to a C1 to C20 alkyl group, the term “alkenyl group” may refer to a C2 to C20 alkenyl group, the term “cycloalkenyl group” may refer to a C3 to C20 cycloalkenyl group, the term “heterocycloalkenyl group” may refer to a C3 to C20 heterocycloalkenyl group, the term “aryl group” may refer to a C6 to C20 aryl group, the term “arylalkyl group” may refer to a C7 to C20 arylalkyl group, the term “alkylene group” may refer to a C1 to C20 alkylene group, the term “arylene group” may refer to a C6 to C20 arylene group, the term “alkylarylene group” may refer to a C7 to C20 alkylarylene group, the term “heteroarylene group” may refer to a C3 to C20 heteroarylene group, and the term “alkoxylene group” may refer to a C1 to C20 alkoxylene group.

As used herein, when specific definition is not otherwise provided, “substituted” may refer to replacement of at least one hydrogen atom by a substituent selected from a halogen atom (F, Cl, Br, or I), a hydroxy group, a C1 to C20 alkoxy group, a nitro group, a cyano group, an amine group, an imino group, an azido group, an amidino group, a hydrazino group, a hydrazono group, a carbonyl group, a carbamyl group, a thiol group. an ester group, an ether group, a carboxyl group or a salt thereof, a sulfonic acid group or a salt thereof, a phosphoric acid or a salt thereof, a C1 to C20 alkyl group, a C2 to C20 alkenyl group, a C2 to C20 alkynyl group, a C6 to C20 aryl group, a C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, a C3 to C20 heteroaryl group, or a combination thereof.

As used herein, when specific definition is not otherwise provided, “hetero” may refer to inclusion of at least one heteroatom of N, O, S, and P, in chemical formula.

As used herein, when specific definition is not otherwise provided, “(meth)acrylate” may refer to both “acrylate” and “methacrylate”.

As used herein, when specific definition is not otherwise provided, the term “combination” may refer to mixing or copolymerization. In addition, “copolymerization” may refer to block copolymerization, alternating copolymerization or random copolymerization, and “copolymer” may refer to a block copolymer, an alternate copolymer, or a random copolymer.

As used herein, when specific definition is not otherwise provided, an unsaturated bond includes a bond between other atoms such as a carbonyl bond, or an azo bond as well as a multi-bond between carbon-carbon atoms.

As used herein, when a definition is not otherwise provided, hydrogen is bonded at the position when a chemical bond is not drawn in chemical formula where supposed to be given.

In addition, as used herein, when a definition is not otherwise provided, “*” may refer to a linking point with the same or different atom or chemical formula.

A positive photosensitive resin composition according to an embodiment may include, e.g., (A) an alkali soluble resin; (B) a photosensitive diazoquinone compound; (C) a dissolution controlling agent represented by Chemical Formula 1; (D) a cross-linking agent represented by Chemical Formula 2; and (E) a solvent. In an implementation, the dissolution controlling agent and the cross-linking agent may be included in a weight ratio of, e.g., about 1:1 to about 1:2.

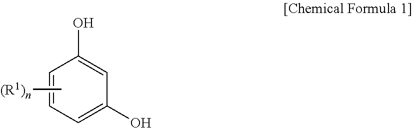

In Chemical Formula 1,

R¹ may be or may include, e.g., a substituted or unsubstituted C1 to C20 alkyl group, and

n may be, e.g., an integer of 0 or 1.

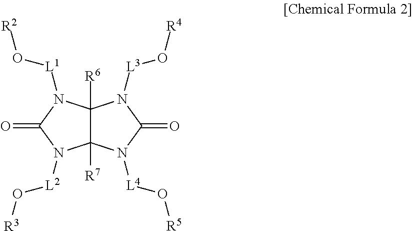

In Chemical Formula 2,

R² to R⁷ may each independently be or include, e.g., a hydrogen atom or a substituted or unsubstituted C1 to C20 alkyl group, and

L¹ to L⁴ may each independently be or include, e.g., a substituted or unsubstituted C1 to C20 alkylene group.

A semiconductor circuit protective layer may have mechanical properties, e.g., resistance against internal/external environments. An embodiment may provide a positive photosensitive resin composition including a multi-functional cross-linking agent in an appropriate amount to help improve heat resistance and elasticity. The composition may also include a resorcinol dissolution-controlling agent having a faster dissolution rate than that of an alkali soluble resin substituted with an alkyl group to obtain a development balance and above all, having reliability. For example, a low coefficient of thermal expansion and high mechanical strength may be achieved by including the cross-linking agent and the dissolution controlling agent in a particular content ratio.

Hereinafter, each component is specifically described.

### Dissolution Controlling Agent

The positive photosensitive resin composition according to an embodiment may include the dissolution controlling agent represented by Chemical Formula 1. The dissolution controlling agent may be used along with the cross-linking agent that will be described in greater detail below. In an implementation, the dissolution controlling agent and the cross-linking agent may be used or included in the composition in a weight ratio of, e.g., about 1:1 to about 1:2, about 1:1 to about 1:1.6, or about 1:1 to about 1:1.5, which may help improve reliability.

In the case of the semiconductor circuit protective layer (PSPI), stress-relaxation against internal/external environments may be made easily, and low coefficients of thermal expansion and more than adequate mechanical properties may be exhibited in order to help prevent thermal stresses and adhesive peeling, crack, or shortage which could occur during high temperature operation of a device, and thus to obtain high reliability. For example, a mixing ratio of the dissolution controlling agent and the cross-linking agent in the composition may be considered. In an implementation, the dissolution controlling agent and the cross-linking agent may be mixed or included in a weight ratio of, e.g., about 1:1 to about 1:2, about 1:1 to about 1:1.6, or about 1:1 to about 1:1.5, in an effort to help achieve low coefficient of thermal expansion and excellent mechanical properties. For example, if the dissolution controlling agent were to be included in a greater amount than the cross-linking agent, both thermal and mechanical properties could be deteriorated. If the cross-linking agent were to be included in an amount exceeding twice the content of the dissolution controlling agent, thermal characteristics could be deteriorated.

The dissolution controlling agent represented by Chemical Formula 1, which is a resorcinol polyphenolic compound, may have a very high dissolution rate. Furthermore, it may have an alkyl group as a substituent (e.g., at a specific position), thereby adjusting a development balance of the photosensitive resin composition.

If n in Chemical Formula 1 were to be an integer of 2 or more, a dissolution force (e.g., solubility) of the positive photosensitive resin composition may be decreased. The dissolution controlling agent represented by Chemical Formula 1 may be a dissolution controlling agent of a low molecular weight type. For example, if n in Chemical Formula 1 were to be an integer of 2 or more, a dissolution force could be deteriorated due to a steric hindrance effect of the alkyl group.

In an implementation, the dissolution controlling agent represented by Chemical Formula 1 may be, e.g., represented by Chemical Formula 1-1 or Chemical Formula 1-2.

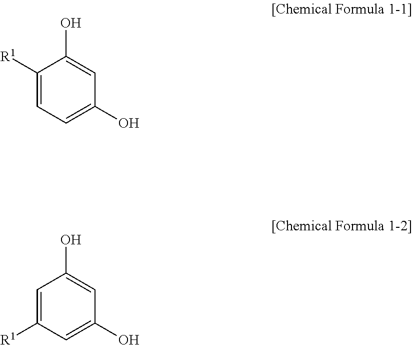

In Chemical Formula 1-1 and Chemical Formula 1-2, R¹ may be or may include, e.g., a substituted or unsubstituted C1 to C20 alkyl group.

In an implementation, in Chemical Formula 1-1 and Chemical Formula 1-2, R¹ may be, e.g., an unsubstituted C1 to C6 alkyl group.

In an implementation, the dissolution controlling agent represented by Chemical Formula 1 may be, e.g., represented by one of Chemical Formula 1A to Chemical Formula 1E.

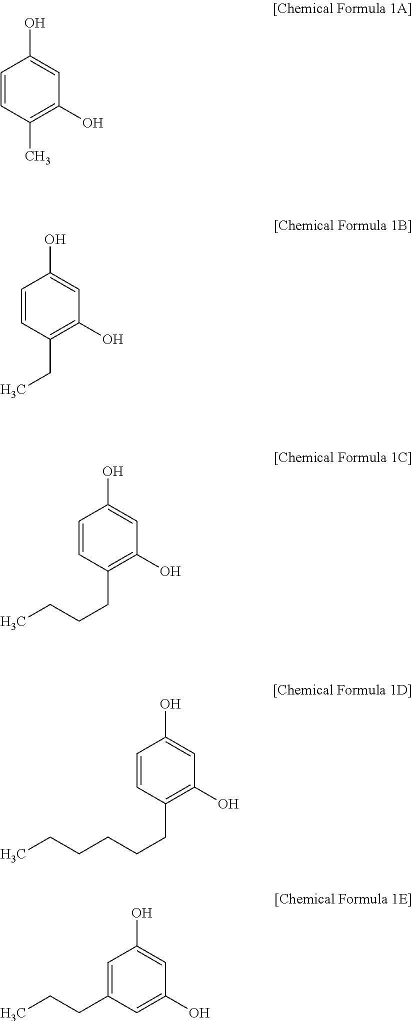

In an implementation, the dissolution controlling agent may be included in the composition in an amount of, e.g., about 10 parts by weight to about 30 parts by weight, based on 100 parts by weight of the alkali soluble resin. When the content of dissolution controlling agent is included in the range, a dissolution rate and sensitivity of an exposed portion when developing with alkali aqueous solution may be increased, and a high resolution patterning may be possible without a resulting developing residue (e.g., scum) during development.

### Cross-linking Agent

The positive photosensitive resin composition according to an embodiment may include the cross-linking agent represented by Chemical Formula 2. The cross-linking agent may be used in conjunction with the dissolution controlling agent as described above. In an implementation, the dissolution controlling agent and the cross-linking agent may be used or included in the composition in a weight ratio of, e.g., about 1:1 to about 1:2, about 1:1 to about 1:1.6, or about 1:1 to about 1:1.5, which may help improve reliability.

According to an embodiment, the cross-linking agent having a structure represented by Chemical Formula 2 may help provide a photosensitive resin composition having a fortified protective layer function, e.g., improved heat resistance, mechanical properties, and the like.

In an implementation, in Chemical Formula 2, R² to R⁵ may each independently be, e.g., a substituted or unsubstituted C1 to C20 alkyl group, R⁶ and R⁷ may each be, e.g., a hydrogen atom, and L¹ to L⁴ may each independently be, e.g., a substituted or unsubstituted C1 to C20 alkylene group.

The cross-linking agent may react with a hydroxy group of the alkali-soluble resin that will be described below to form a cross-linking structure and may help improve resistance to thermal and mechanical stresses that may occur during the process. For example, it may help effectively protect an electronic device such as a semiconductor circuit, and the like.

In an implementation, the cross-linking agent may be included in an amount of, e.g., about 10 parts by weight to about 60 parts by weight or about 10 parts by weight to about 45 parts by weight, based on 100 parts by weight of the alkali soluble resin.

### Alkali Soluble Resin

The alkali soluble resin may be a resin having a hydroxy group. In an implementation, the alkali soluble resin may include, e.g., a polybenzoxazole precursor (a polybenzoxazole compound), a polyimide precursor (a polyimide compound), a novolac resin, a bisphenol A resin, a bisphenol F resin, a (meth)acrylate resin, a combination thereof, or the like.

In an implementation, the polybenzoxazole precursor may include a structural unit represented by Chemical Formula 3.

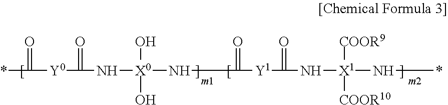

In Chemical Formula 3,

X⁰ and X¹ may each independently be or include, e.g., a substituted or unsubstituted C6 to C30 aromatic organic group,

Y⁰ and Y¹ may each independently be or include, e.g., a substituted or unsubstituted C6 to C30 aromatic organic group, a substituted or unsubstituted divalent to hexavalent C1 to C30 aliphatic organic group, or a substituted or unsubstituted divalent to hexavalent C3 to C30 alicyclic organic group,

R⁹ and R¹⁰ may each independently be or include, e.g., a hydrogen atom, a substituted or unsubstituted C1 to C20 alkyl group, a substituted or unsubstituted C3 to C20 cycloalkyl group, a substituted or unsubstituted C6 to C20 aryl group, a metal ion, or an ammonium ion, and

m1 and m2 may each independently be, e.g., an integer of 0 to 100,000. In an implementation, m1+m2 may be, e.g., an integer of 2 or more.

In an implementation, the polyimide precursor may include a structural unit represented by Chemical Formula 4.

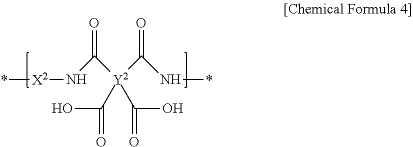

In Chemical Formula 4,

X² may be or may include, e.g., a substituted or unsubstituted C6 to C30 aromatic organic group, a substituted or unsubstituted divalent to hexavalent C1 to C30 aliphatic organic group, or a substituted or unsubstituted divalent to hexavalent C3 to C30 alicyclic organic group, and

Y² may be or may include, e.g., a substituted or unsubstituted C6 to C30 aromatic organic group, a substituted or unsubstituted quadrivalent to hexavalent C1 to C30 aliphatic organic group, or a substituted or unsubstituted quadrivalent to hexavalent C3 to C30 alicyclic organic group.

In an implementation, in Chemical Formula 3, X¹ may be, e.g., an aromatic organic group and may be a moiety derived from aromatic diamine.

In an implementation, the aromatic diamine may include, e.g., 3,3′-diamino-4,4′-dihydroxybiphenyl, 4,4′-diamino-3,3′-dihydroxybiphenyl, bis(3-amino-4-hydroxyphenyl)propane, bis(4-amino-3-hydroxyphenyl)propane, bis(3-amino-4-hydroxyphenyl)sulfone, bis(4-amino-3-hydroxyphenyl)sulfone, 2,2-bis(3-amino-4-hydroxyphenyl)-1,1,1,3,3,3-hexafluoropropane, 2,2-bis(4-amino-3-hydroxyphenyl)-1,1,1,3,3,3-hexafluoropropane, 2,2-bis(3-amino-4-hydroxy-5-trifluoromethylphenyl)hexafluoropropane, 2,2-bis(3-amino-4-hydroxy-6-trifluoromethylphenyl)hexafluoropropane, 2,2-bis(3-amino-4-hydroxy-2-trifluoromethylphenyl)hexafluoropropane, 2,2-bis(4-amino-3-hydroxy-5-trifluoromethylphenyl)hexafluoropropane, 2,2-bis(4-amino-3-hydroxy-6-trifluoromethylphenyl)hexafluoropropane, 2,2-bis(4-amino-3-hydroxy-2-trifluoromethylphenyl)hexafluoropropane, 2,2-bis(3-amino-4-hydroxy-5-pentafluoroethylphenyl)hexafluoropropane, 2-(3-amino-4-hydroxy-5-trifluoromethylphenyl)-2-(3-amino-4-hydroxy-5-pentafluoroethylphenyl)hexafluoropropane, 2-(3-amino-4-hydroxy-5-trifluoromethylphenyl)-2-(3-hydroxy-4-amino-5-trifluoromethylphenyl)hexafluoropropane, 2-(3-amino-4-hydroxy-5-trifluoromethylphenyl)-2-(3-hydroxy-4-amino-6-trifluoromethylphenyl)hexafluoropropane, 2-(3-amino-4-hydroxy-5-trifluoromethylphenyl)-2-(3-hydroxy-4-amino-2-trifluoromethylphenyl)hexafluoropropane, 2-(3-amino-4-hydroxy-2-trifluoromethylphenyl)-2-(3-hydroxy-4-amino-5-trifluoromethylphenyl)hexafluoropropane, or 2-(3-amino-4-hydroxy-6-trifluoromethylphenyl)-2-(3-hydroxy-4-amino-5-trifluoromethylphenyl)hexafluoropropane.

In an implementation, in Chemical Formula 3, X⁰ and X¹ may each independently be, e.g., a functional group represented by Chemical Formula 5 or Chemical Formula 6.

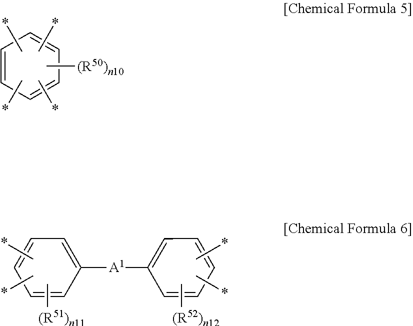

In Chemical Formula 5 and Chemical Formula 6,

A¹ may be, e.g., a single bond, O, CO, CR⁴⁷R⁴⁸, SO₂, or S, R⁴⁷ and R⁴⁸ may each independently be or include, e.g., a hydrogen atom or a substituted or unsubstituted C1 to C30 alkyl group. In an implementation, R⁴⁷ and R⁴⁸ may each independently be or include, e.g., a C1 to C30 fluoroalkyl group.

R⁵⁰ to R⁵² may each independently be or include, e.g., a hydrogen atom, a substituted or unsubstituted C1 to C30 alkyl group, a substituted or unsubstituted C1 to C30 carboxyl group, a hydroxy group, or a thiol group.

n10 may be, e.g., an integer of 0 to 2. n11 and n12 may each independently be, e.g., an integer of 0 to 3.

In an implementation, in Chemical Formula 3, Y⁰ and Y¹ may each independently be, e.g., an aromatic organic group, a divalent to hexavalent aliphatic organic group, or a divalent to hexavalent alicyclic organic group. In an implementation, in Chemical Formula 3, Y⁰ and Y¹ may each independently be, e.g., a moiety of dicarboxylic acid or a moiety of a dicarboxylic acid derivative. In an implementation, in Chemical Formula 3, Y⁰ and Y¹ may each independently be, e.g., an aromatic organic group or a divalent to hexavalent alicyclic organic group.

In an implementation, the dicarboxylic acid derivative may include, e.g., 4,4′-oxydibenzoylchloride, diphenyloxydicarbonyl dichloride, bis(phenylcarbonylchloride)sulfone, bis(phenylcarbonylchloride)ether, bis(phenylcarbonylchloride)phenone, phthaloyl dichloride, terephthaloyl dichloride, isophthaloyl dichloride, dicarbonyl dichloride, diphenyloxydicarboxylate dibenzotriazole, or a combination thereof.

In an implementation, in Chemical Formula 3, Y⁰ and Y¹ may each independently be, e.g., a functional group represented by Chemical Formula 7 to Chemical Formula 9.

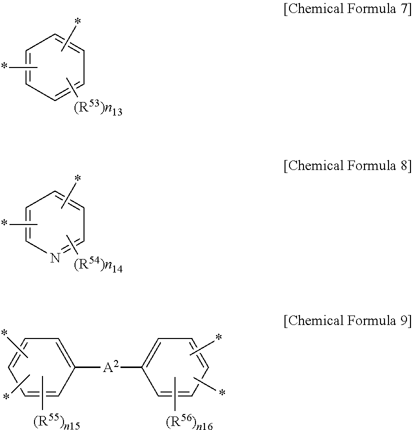

In Chemical Formula 7 to Chemical Formula 9,

R⁵³ to R⁵⁶ may each independently be or include, e.g., a hydrogen atom or a substituted or unsubstituted C1 to C30 alkyl group,

n13 and n14 may each independently be, e.g., an integer of 0 to 4, n15 and n16 may each independently be, e.g., an integer of 0 to 3, and

A² may be, e.g., a single bond, O, CR⁴⁷R⁴⁸, CO, CONH, S, or SO₂, in which R⁴⁷ and R⁴⁸ may each independently be or include, e.g., a hydrogen atom or a substituted or unsubstituted C1 to C30 alkyl group. In an implementation, R⁴⁷ and R⁴⁸ may each independently be or include, e.g., a C1 to C30 fluoroalkyl group.

In an implementation, in Chemical Formula 4, X² may be, e.g., an aromatic organic group, a divalent to hexavalent aliphatic organic group, or a divalent to hexavalent alicyclic organic group. In an implementation, X² may be, e.g., an aromatic organic group or a divalent to hexavalent alicyclic organic group.

In an implementation, X² may be, e.g., a moiety derived from an aromatic diamine, an alicyclic diamine, or a silicon diamine. The aromatic diamine, alicyclic diamine, and silicon diamine may be used alone or in a combination of one or more.

In an implementation, the aromatic diamine may include, e.g., 3,4′-diaminodiphenylether, 4,4′-diaminodiphenylether, 3,4′-diaminodiphenylmethane, 4,4′-diaminodiphenylmethane, 4,4′-diaminodiphenylsulfone, 4,4′-diaminodiphenylsulfide, benzidine, m-phenylenediamine, p-phenylenediamine, 1,5-naphthalenediamine, 2,6-naphthalenediamine, bis[4-(4-aminophenoxy)phenyl]sulfone, bis(3-aminophenoxyphenyl)sulfone, bis(4-aminophenoxy)biphenyl, bis[4-(4-aminophenoxy)phenyl]ether, 1,4-bis(4-aminophenoxy)benzene, the forgoing compounds including an aromatic ring substituted with alkyl group or a halogen, or a combination thereof.

In an implementation, the alicyclic diamine may include, e.g., 1,2-cyclohexyl diamine, 1,3-cyclohexyl diamine, or a combination thereof.

In an implementation, the silicon diamine may include, e.g., bis(4-aminophenyl)dimethylsilane, bis(4-aminophenyl)tetramethylsiloxane, bis(p-aminophenyl)tetramethyldisiloxane, bis(γ-aminopropyl)tetramethyldisiloxane, 1,4-bis(γ-aminopropyldimethylsilyl)benzene, bis(4-aminobutyl)tetramethyldisiloxane, bis(γ-aminopropyl)tetraphenyldisiloxane, 1,3-bis(aminopropyl)tetramethyldisiloxane, or a combination thereof.

In an implementation, in Chemical Formula 4, Y² may be, e.g., an aromatic organic group, a quadrivalent to hexavalent aliphatic organic group, or a quadrivalent to hexavalent alicyclic organic group. In an implementation, Y² may be, e.g., an aromatic organic group or quadrivalent to hexavalent alicyclic organic groups.

In an implementation, Y² may be, e.g., a moiety derived from aromatic acid dianhydride or alicyclic acid dianhydride. The aromatic acid dianhydride and the alicyclic acid dianhydride may be used alone or in a combination of one or more.

In an implementation, the aromatic acid dianhydride may include, e.g., benzophenone tetracarboxylic dianhydride such as pyromellitic dianhydride; benzophenone-3,3′,4,4′-tetracarboxylic dianhydride, and the like; oxydiphthalic dianhydride such as 4,4′-oxydiphthalic dianhydride; biphthalic dianhydride such as 3,3′,4,4′-biphthalic dianhydride; (hexafluoroisopropyledene)diphthalic dianhydride such as 4,4′-(hexafluoroisopropyledene)diphthalic dianhydride; naphthalene-1,4,5,8-tetracarboxylic dianhydride; 3,4,9,10-perylenetetracarboxylic dianhydride, or the like.

In an implementation, the alicyclic acid dianhydride may include, e.g., 1,2,3,4-cyclobutanetetracarboxylic dianhydride, 1,2,3,4-cyclopentanetetracarboxylic dianhydride, 5-(2,5-dioxotetrahydrofuryl)-3-methyl-cyclohexane-1,2-dicarboxylic anhydride, 4-(2,5-dioxotetrahydrofuran-3-yl)-tetralin-1,2-dicarboxylic anhydride, bicyclooctene-2,3,5,6-tetracarboxylic dianhydride, bicyclooctene-1,2,4,5-tetracarboxylic dianhydride, or the like.

In an implementation, the alkali soluble resin may include, e.g., a polybenzoxazole precursor, a polyimide precursor, a novolac resin, or a combination thereof.

In an implementation, the alkali soluble resin may include, e.g., a polybenzoxazole precursor and a cresol novolac resin. When both the polybenzoxazole precursor and the cresol novolac resin are included, it may be advantageous in controlling the developing rate and forming fine patterns.

The alkali soluble resin may have a weight average molecular weight (Mw) of, e.g., about 3,000 g/mol to about 300,000 g/mol or about 5,000 g/mol to about 30,000 g/mol. When the alkali soluble resin has the weight average molecular weight within (Mw) the ranges, a sufficient film residue ratio in a non-exposed portion may be obtained during development with an alkali aqueous solution, and efficient patterning may be performed.

### Photosensitive Diazoquinone Compound

The photosensitive diazoquinone compound may be, e.g., a compound having a 1,2-benzoquinone diazide structure or 1,2-naphthoquinone diazide structure.

In an implementation, the photosensitive diazoquinone compound may include, e.g., a compound represented by one of Chemical Formula 10 and Chemical Formula 12 to Chemical Formula 14.

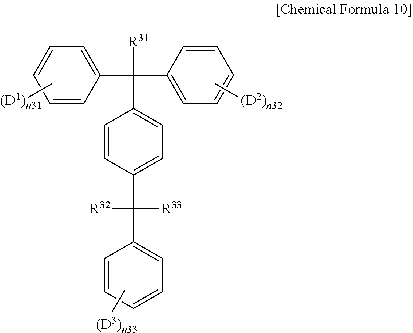

In Chemical Formula 10,

R³¹ to R³³ may each independently be or include, e.g., a hydrogen atom or a substituted or unsubstituted alkyl group. In an implementation, R³¹ to R³³ may be, e.g., CH₃.

D¹ to D³ may each independently be OQ. In an implementation, Q may be, e.g., hydrogen, a functional group represented by Chemical Formula 11a, or a functional group represented by Chemical Formula 11b. In an implementation, all Qs are not simultaneously hydrogen.

n31 to n33 may each independently be, e.g., an integer of 1 to 5.

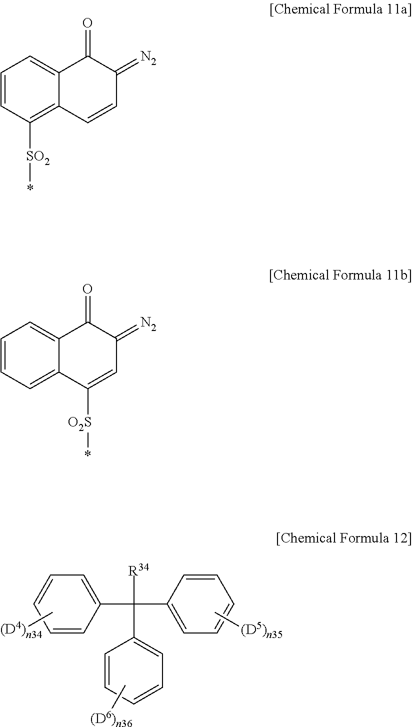

In Chemical Formula 12,

R³⁴ may be or may include, e.g., a hydrogen atom or a substituted or unsubstituted alkyl group,

D⁴ to D⁶ may each independently be, e.g., OQ. In an implementation, Q may be defined the same as Q of Chemical Formula 10.

n34 to n36 may each independently be, e.g., an integer of 1 to 5.

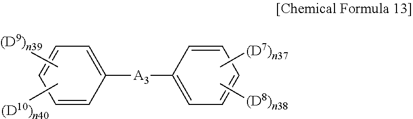

In Chemical Formula 13,

A₃ may be, e.g., CO or CR⁵⁰⁰R⁵⁰¹, in which R⁵⁰⁰ and R⁵⁰¹ may each independently be or include, e.g., a substituted or unsubstituted alkyl group.

D⁷ to D¹⁰ may each independently be or include, e.g., a hydrogen atom, a substituted or unsubstituted alkyl group, OQ, or NHQ. Q may be defined the same as Q of Chemical Formula 10.

n37, n38, n39, and n40 may each independently be, e.g., an integer of 1 to 4, and

n37+n38 and n39+n40 may each independently be, e.g., an integer of less than or equal to 5.

In an implementation, at least one of the D⁷ to D¹⁰ may be OQ. In an implementation, one aromatic ring may include one to three OQ and the other aromatic ring may include one to four OQ.

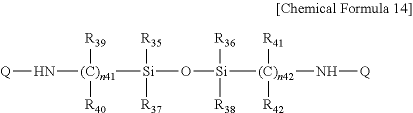

In Chemical Formula 14,

R₃₅ to R₄₂ may each independently be or include, e.g., a hydrogen atom or a substituted or unsubstituted alkyl group,

n41 and n42 may each independently be, e.g., an integer of 1 to 5. In an implementation, n41 and n42 may each independently be, e.g., an integer of 2 to 4, and

Q may be defined the same as Q of Chemical Formula 10.

In an implementation, the photosensitive diazoquinone compound may be included in an amount of, e.g., about 1 part by weight to about 100 parts by weight or about 5 parts by weight to about 50 parts by weight, based on 100 parts by weight of the alkali soluble resin. When the photosensitive diazoquinone compound is included within the above range, the pattern may be well-formed without a residue from exposure, and a film thickness loss during development may be prevented and a good pattern may be obtained.

### Solvent

The photosensitive resin composition may include a solvent that is capable of dissolving each of the alkali soluble resin, the photosensitive diazoquinone compound, the cross-linking agent, and the dissolution controlling agent, and the like.

In an implementation, the solvent may be an organic solvent, e.g., N-methyl-2-pyrrolidone, gamma-butyrolactone, N,N-dimethyl acetamide, dimethylsulfoxide, diethylene glycoldimethylether, diethylene glycoldiethylether, diethylene glycoldibutylether, propylene glycolmonomethylether, dipropylene glycolmonomethylether, propylene glycolmonomethyl ether acetate, methyl lactate, ethyl lactate, butyl lactate, methyl-1,3-butylene glycolacetate, 1,3-butylene glycol-3-monomethylether, methyl pyruvate, ethyl pyruvate, methyl-3-methoxy propionate, or a combination thereof.

The solvent may be appropriately selected according a process of forming a photosensitive resin layer such as spin coating, slit die coating, and the like.

In an implementation, the solvent may be included in an amount of, e.g., about 100 parts by weight to about 500 parts by weight or about 100 parts by weight to about 400 parts by weight, based on 100 parts by weight of the alkali soluble resin. When the solvent is included within the ranges, a coating layer may have a sufficient thickness and excellent solubility, and coating properties may be improved.

### Other Additives

In an implementation, the positive photosensitive resin composition according to an embodiment may further include other additives.

In an implementation, the photosensitive resin composition may include, e.g., additives of diacid such as malonic acid, alkanol amine such as 3-amino-1,2-propanediol, a leveling agent, a silane coupling agent, a surfactant, an epoxy compound, a radical polymerization initiator, a thermal latent acid generator, or a combination thereof, in order to help prevent a stain of the film during coating, leveling improvement, or residues generation due to non-development. Use amounts of the additives may be controlled depending on desired properties.

In an implementation, the silane coupling agent may have a reactive substituent such as a vinyl group, a carboxyl group, a methacryloxy group, an isocyanate group, an epoxy group, or the like, in order to help improve close-contacting properties with a substrate.

Examples of the silane coupling agent may include trimethoxysilylbenzoic acid, γ-methacryloxypropyltrimethoxysilane, vinyltriacetoxysilane, vinyltrimethoxysilane, γ-isocyanate propyltriethoxysilane, γ-glycidoxypropyltrimethoxysilane, β-(3,4-epoxycyclohexyl)ethyltrimethoxysilane, and the like, and may be used alone or in a mixture of two or more.

The silane coupling agent may be included in an amount of, e.g., about 0.01 parts by weight to about 10 parts by weight, based on 100 parts by weight of the photosensitive resin composition. When the silane-based coupling agent is included within the ranges, close-contacting properties, storage capability, and the like may be improved.

For example, the surfactant may be added to help prevent strains of a film thickness or to improve developability, and may include a fluorine surfactant and/or a silicone surfactant.

Examples of the fluorine surfactant may include a commercial fluorine surfactant such as BM-1000® and BM-1100® of BM Chemie Inc.; MEGAFACE F 142D®, MEGAFACE F 172®, MEGAFACE F 173®, MEGAFACE F 183®, and MEGAFACE F 554® of Dainippon Ink Kagaku Kogyo Co., Ltd.; FULORAD FC-135®, FULORAD FC-170C®, FULORAD FC-430®, and FULORAD FC-431® of Sumitomo 3M Co., Ltd.; SURFLON S-112®, SURFLON S-113®, SURFLON S-131®, SURFLON S-141®, and SURFLON S-145® of Asahi Glass Co., Ltd.; SH-28PA®, SH-190®, SH-193®, SZ-6032®, and SF-8428®, and the like (Toray Silicone Co., Ltd.).

Examples of the silicone surfactant may include BYK-307, BYK-333, BYK-361N, BYK-051, BYK-052, BYK-053, BYK-067A, BYK-077, BYK-301, BYK-322, BYK-325, and the like, which are made by BYK Chem and commercially available.

The surfactant may be included in an amount of, e.g., about 0.001 parts by weight to about 5 parts by weight, based on 100 parts by weight of the photosensitive resin composition. When the surfactant is included within the range, coating uniformity may be secured, a stain may not be produced and wetting on an ITO substrate or a glass substrate may be improved.

In an implementation, the photosensitive resin composition may further include an epoxy compound to help improve a close-contacting force and the like as an additive. The epoxy compound may include, e.g., an epoxy novolac acryl carboxylate resin, an ortho cresol novolac epoxy resin, a phenol novolac epoxy resin, a tetramethyl biphenyl epoxy resin, a bisphenol A epoxy resin, an alicyclic epoxy resin, or a combination thereof.

When the epoxy compound is further included, a radical polymerization initiator such as a peroxide initiator or an azobis initiator may be further included.

The epoxy compound may be included in an amount of, e.g., about 0.01 parts by weight to about 5 parts by weight, based on 100 parts by weight of the photosensitive resin composition. When the epoxy compound is included within the range, storage capability, close-contacting force, and other characteristics may be improved.

In an implementation, the photosensitive resin composition may further include the thermal latent acid generator. In an implementation, the thermal latent acid generator may include, e.g., arylsulfonic acid such as p-toluene sulfonic acid or benzene sulfonic acid; perfluoroalkyl sulfonic acid such as trifluoromethane sulfonic acid or trifluorobutane sulfonic acid; alkylsulfonic acid such as methane sulfonic acid, ethane sulfonic acid, or butane sulfonic acid; or a combination thereof.

The latent thermal acid generator may be a catalyst for a dehydration reaction and a cyclization reaction of the polybenzoxazole precursor that is polyamide including a phenolic hydroxy group, and a cyclization reaction may be performed smoothly even if a curing temperature is decreased.

In an implementation, the positive photosensitive resin composition may further include other additives, e.g., an antioxidant, a stabilizer, or the like in a predetermined amount, unless properties are deteriorated.

Another embodiment provides a photosensitive resin layer manufactured by exposure, development, and curing of the aforementioned positive photosensitive resin composition.

A method of manufacturing the photosensitive resin layer is as follows.

(1) Coating and Layer Formation

The positive photosensitive resin composition may be coated to have a desired thickness on a substrate (e.g., a glass substrate or an ITO substrate which has undergone a pretreatment) using a spin or slit coating method, a roll coating method, a screen-printing method, an applicator method, or the like. Then, the coated substrate may be heated at a temperature ranging from about 70° C. to about 150° C. for about 1 minute to about 10 minutes to remove a solvent and to form a layer.

(2) Exposure

The obtained photosensitive resin layer may be irradiated with an active ray of about 200 nm to about 500 nm after putting a mask with a predetermined shape to form a desired pattern. The irradiation may be performed by using a light source such as a mercury lamp with a low pressure, a high pressure, or an ultrahigh pressure, a metal halide lamp, an argon gas laser, and the like. An X ray, an electron beam, and the like may also be used as desired.

The exposure dose may differ depending on a type of each component of the composition, its combination ratio, and a dry film thickness, and may be less than or equal to 500 mJ/cm² (according to a 365 nm sensor) when a high pressure mercury lamp is used.

(3) Development

In a developing method, after the exposure step, the exposed part may be dissolved and removed by using a developing solution to leave only a non-exposed portion to obtain a pattern.

(4) Post-process Process

An image pattern obtained by development in the above processes may be post-heated in order to obtain a pattern having improved heat resistance, light resistance, close-contacting properties, crack resistance, chemical resistance, high strength, and storage stability. For example, after development, it may be heated in a convection oven at 250° C. for 1 hour.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### EXAMPLE

### Synthesis of Alkali Soluble Resin

11.0 g of bis(3-amino-4-hydroxyphenyl) (phenyl)phosphine oxide was dissolved in 280 g of N-methyl-2-pyrrolidone (NMP) in a four-necked flask equipped with a stirrer, a temperature controller, a nitrogen gas injector, and a condenser, while nitrogen was passed therethrough. When the solid was completely dissolved, 9.9 g of pyridine was added to the solution, and while the temperature was maintained at 0° C. to 5° C., another solution prepared by dissolving 13.3 g of 4,4′-oxydibenzonyl chloride in 142 g of N-methyl-2-pyrrolidone (NMP) was slowly added thereto in a dropwise fashion for 30 minutes. After the addition, the obtained mixture was reacted at 0° C. to 5° C. for 1 hour and then, stirred for one hour by increasing the temperature up to ambient temperature. 1.6 g of 5-norbornene-2,3-dicarboxyl anhydride was added thereto and then, stirred at 70° C. for 24 hours to complete the reaction. The reaction mixture was put in a solution of water/methanol=10/1 (a volume ratio) to form precipitates, and the precipitates were filtered and sufficiently washed with water and then, dried at 80° C. under vacuum for at least 24 hours to prepare a polybenzoxazole (PBO) precursor having a weight average molecular weight of 11,100 g/mol.

### Preparation of Photosensitive Resin Composition

### Examples 1 to 8 and Comparative Examples 1 to 9

Based on compositions provided in Tables 1 and 2, the polybenzoxazole precursor was added to and dissolved in γ (gamma)-butyrolactone (GBL), a photosensitive diazoquinone compound, a cresol novolac resin, a cross-linking agent, a dissolution controlling agent, and a silane coupling agent were added thereto and then, stirred for one hour at ambient temperature, and then, a leveling agent was further added thereto and dissolved therein and then, filtered with a 0.45 μm PE syringe filter to obtain positive photosensitive resin compositions.

TABLE 1
(unit: g)

| | | Ex. 1 | Ex. 2 | Ex. 3 | Ex. 4 | Ex. 5 | Ex. 6 | Ex. 7 | Ex. 8 |
|---|---|---|---|---|---|---|---|---|---|
| (A) Alkali | (A-1) | 25.0 | 25.0 | 25.0 | 25.0 | 25.0 | 25.0 | 25.0 | 25.0 |
| soluble resin | (A-2) | 6.5 | 6.5 | 6.5 | 6.5 | 6.5 | 6.5 | 6.5 | 6.5 |
| (B) Photosensitive | | 6.0 | 6.0 | 6.0 | 6.0 | 6.0 | 6.0 | 6.0 | 6.0 |
| diazoquinone compound | | | | | | | | | |
| (C) | (C-1) | 5.0 | — | — | — | — | 5.0 | 4.5 | 6.0 |
| Dissolution | (C-2) | — | 5.0 | — | — | — | — | — | — |
| controlling | (C-3) | — | — | 5.0 | — | — | — | — | — |
| agent | (C-4) | — | — | — | 5.0 | — | — | — | — |
| | (C-5) | — | — | — | — | 5.0 | — | — | — |
| (D) Cross-linking agent | (D-1) | 7.5 | 7.5 | 7.5 | 7.5 | 7.5 | 5.0 | 5.0 | 12.0 |
| (E) Solvent | | 49.5 | 49.5 | 49.5 | 49.5 | 49.5 | 51.5 | 52.0 | 44.0 |
| (F) Other | (F-1) | 0.3 | 0.3 | 0.3 | 0.3 | 0.3 | 0.3 | 0.3 | 0.3 |
| additives | (F-2) | 0.2 | 0.2 | 0.2 | 0.2 | 0.2 | 0.2 | 0.2 | 0.2 |

TABLE 2
(unit: g)

| | | Comp. | Comp. | Comp. | Comp. | Comp. | Comp. | Comp. | Comp. | Comp. |
|---|---|---|---|---|---|---|---|---|---|---|
| | | Ex. 1 | Ex. 2 | Ex. 3 | Ex. 4 | Ex. 5 | Ex. 6 | Ex. 7 | Ex. 8 | Ex. 9 |
| (A) Alkali | (A-1) | 25.0 | 25.0 | 25.0 | 25.0 | 25.0 | 25.0 | 25.0 | 25.0 | 25.0 |
| soluble resin | (A-2) | 6.5 | 6.5 | 6.5 | 6.5 | 6.5 | 6.5 | 6.5 | 6.5 | 6.5 |
| (B) Photosensitive | | 6.0 | 6.0 | 6.0 | 6.0 | 6.0 | 6.0 | 6.0 | 6.0 | 6.0 |
| diazoquinone compound | | | | | | | | | | |
| (C) | (C-1) | 5.0 | — | — | — | — | — | 5.0 | 4.0 | 5.0 |
| Dissolution | (C-6) | — | 5.0 | — | — | — | — | — | — | — |
| controlling | (C-7) | — | — | 5.0 | — | — | — | — | — | — |
| agent | (C-8) | — | — | | 5.0 | — | — | — | — | — |
| | (C-9) | — | — | — | | 5.0 | — | — | — | — |
| | (C-10) | — | — | — | — | — | 5.0 | — | — | — |
| (D) Cross- | (D-1) | — | 7.5 | 7.5 | 7.5 | 7.5 | 7.5 | — | 8.4 | 4.5 |
| linking agent | (D-2) | — | — | — | — | — | — | 7.5 | — | — |
| (E) Solvent | | 49.5 | 49.5 | 49.5 | 49.5 | 49.5 | 49.5 | 49.5 | 49.6 | 52.5 |
| (F) Other | (F-1) | 0.3 | 0.3 | 0.3 | 0.3 | 0.3 | 0.3 | 0.3 | 0.3 | 0.3 |
| additives | (F-2) | 0.2 | 0.2 | 0.2 | 0.2 | 0.2 | 0.2 | 0.2 | 0.2 | 0.2 |

(A) Alkali Soluble Resin

(A-1) Polybenzoxazole Precursor

(A-2) Cresol Novolac Resin (KCR-6100)

(B) Photosensitive Diazoquinone Compound (Chemical Formula A)

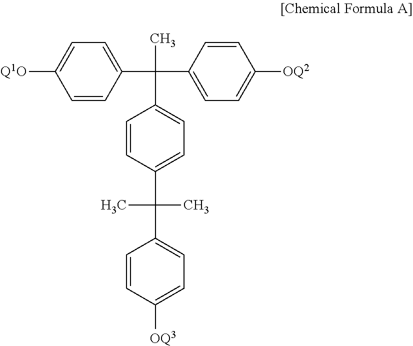

In Chemical Formula A, two of Q¹, Q², and Q³ are

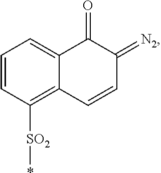

and the remaining one is a hydrogen atom.

(C) Dissolution Controlling Agent

(C-1) Compound Represented by Chemical Formula 1D (TCI Inc.)

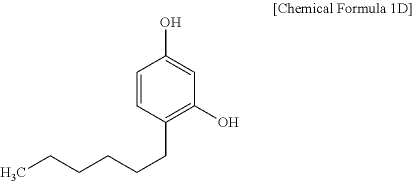

(C-2) Compound Represented by Chemical Formula 1 A (TCI Inc.)

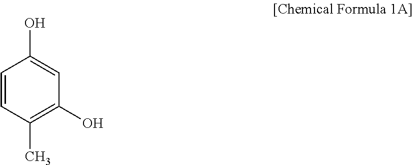

(C-3) Compound Represented by Chemical Formula 1B (TCI Inc.)

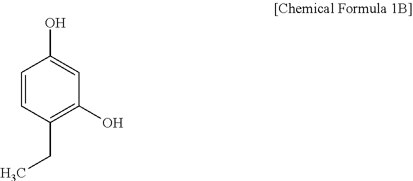

(C-4) Compound Represented by Chemical Formula 1E (TCI Inc.)

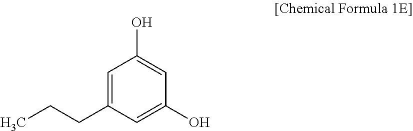

(C-5) Compound Represented by Chemical Formula 1C (TCI Inc.)

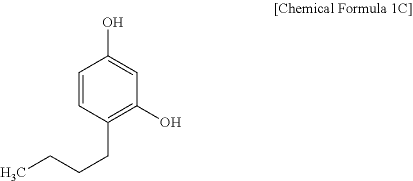

(C-6) Compound Represented by Chemical Formula 1F (TCI Inc.)

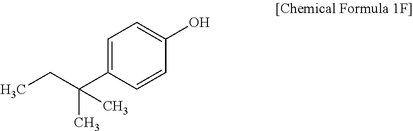

(C-7) Compound Represented by Chemical Formula 1G (TCI Inc.)

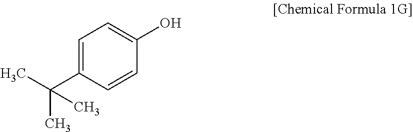

(C-8) Compound Represented by Chemical Formula 1H (TCI Inc.)

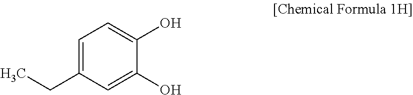

(C-9) Compound Represented by Chemical Formula 1I (TCI Inc.)

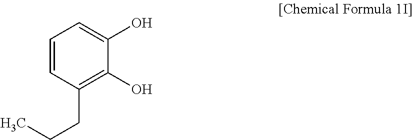

(C-10) Compound Represented by Chemical Formula 1J (TCI Inc.)

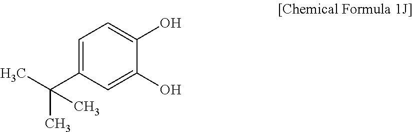

(D) Cross-linking Agent

(D-1) 1,3,4,6-tetrakis(methoxymethyl)glycoluril (TCI Inc.)

(D-2) P-xylene Glycol (TCI Inc.)

(E) Solvent

γ-butyrolactone (GBL)

(F) Other Additives

(F-1) Silane Coupling Agent (KBM-573 (2%))

(F-2) Leveling Agent (BYK-378)

### Evaluation

### Sensitivity

The photosensitive resin compositions according to Example 1 to Example 8 and Comparative Example 1 to Comparative Example 7 were respectively coated on a 10 cm×10 cm ITO glass (resistance of 30Ω), heated on a 100° C. hot plate for 1 minute in a proxy type and then, for 1 minute in a contact type to form 1.2 μm-thick photosensitive resin layers. The photosensitive resin films respectively coated on the substrate were exposed to light by using a mask having variously-sized patterns and changing an exposure dose with UX-1200SM-AKS02 of Ushio Inc. and then, developed in a 2.38% TMAH solution at ambient temperature to dissolve the exposed portion, and washed with pure water for 50 seconds to form patterns.

Sensitivity was evaluated by measuring energy realizing a 20 μm pattern with a reference to a size of a 20 μm square pattern measured by using MX51T-N633MU made by Olympus Corp., and the results are shown in Table 3.

### Film Residue Ratio

The photosensitive resin compositions according to Example 1 to Example 8 and Comparative Example 1 to Comparative Example 7 were respectively coated on a 10 cm×10 cm ITO glass (resistance of 30Ω), heated on a 100° C. hot plate for 2 minutes in a proxy type and then, for 1 minute in a contact type to form 1.2 μm-thick photosensitive resin layers. The photosensitive resin films respectively coated on the substrate were exposed to light by using a mask having variously-sized patterns and changing an exposure dose with UX-1200SM-AKS02 of Ushio Inc. and then, developed in a 2.38% TMAH solution at ambient temperature to dissolve the exposed portion, and washed with pure water for 50 seconds to form patterns. The film residue ratio was calculated according to Equation 1, and the results are shown in Table 3.

Thickness after development/initial(before development)thickness×100(%) [Equation 1]

### Mechanical Properties

The photosensitive resin compositions according to Examples 1 to 8 and Comparative Examples 1 to 7 were respectively spin-coated on a glass plate and sequentially heat-treated at 180° C. for 60 minutes and then, at 300° C. for 60 minutes under a nitrogen stream in a furnace oven to form 10 μm-thick films, and the films were cut on the edge and peeled off by using water. The peeled films were dried at 100° C. for about 30 minutes to remove the water and then, cut into a size of 100×10 mm with reference to ASTM-D882. Elongation at break point was measured through an UTM analysis, and the results are shown in Table 3.

### Thermal Characteristics

The photosensitive resin compositions according to Examples 1 to 8 and

Comparative Examples 1 to 7 were respectively spin-coated on an 8-inch wafer and heat-treated at 300° C. for 30 minutes under a nitrogen stream in a furnace oven to form 10 μm-thick films, and then, the films were cut into a size of 4×25 mm, and a glass transition temperature (T_{g}) and a coefficient of thermal expansion (CTE) thereof were measured by using Q400 TMA (TA Instruments). T_{g} was identified by an inflection point, and the coefficient of thermal expansion was obtained by converting a specimen length transformation depending on a temperature change within a section of 30° C. to 200° C. into a ppm unit.

### Residual Stress

The photosensitive resin compositions according to Examples 1 to 8 and

Comparative Examples 1 to 7 were respectively spin-coated on an 8-inch wafer and heat-treated at 300° C. for 30 minutes under a nitrogen stream in a furnace oven to form 10 μm-thick films, and then, residual stresses of the films were measured by using FLX 2320 (TOHO Technology). (an average of three measurements)

TABLE 3

| | | Film | | | | Young's | |
|---|---|---|---|---|---|---|---|
| | Sensitivity | residue | | CTE | Strength | modulus | Residual |
| | (mJ) | ratio (%) | T_{g} (° C.) | (ppm/° C.) | (Mpa) | (Gpa) | stress |
| Example 1 | 350 | 85 | 295 | 53 | 133 | 3.3 | 37 |
| Example 2 | 330 | 75 | 260 | 78 | 130 | 3.0 | 35 |
| Example 3 | 340 | 78 | 265 | 72 | 135 | 3.1 | 37 |
| Example 4 | 350 | 82 | 275 | 68 | 140 | 3.2 | 39 |
| Example 5 | 370 | 88 | 300 | 50 | 145 | 3.4 | 40 |
| Example 6 | 360 | 88 | 280 | 60 | 128 | 3.1 | 34 |
| Example 7 | 370 | 89 | 278 | 62 | 125 | 3.1 | 34 |
| Example 8 | 350 | 88 | 300 | 50 | 150 | 3.2 | 45 |
| Comparative | 350 | 90 | 200 | 100 | 90.0 | 2.5 | 23 |
| Example 1 | | | | | | | |
| Comparative | 500 | 90 | 300 | 80 | 120 | 2.8 | 41 |
| Example 2 | | | | | | | |
| Comparative | 550 | 92 | 300 | 70 | 125 | 2.7 | 40 |
| Example 3 | | | | | | | |
| Comparative | 600 | 95 | 290 | 70 | 125 | 2.8 | 39 |
| Example 4 | | | | | | | |
| Comparative | 600 | 97 | 300 | 80 | 120 | 2.8 | 39 |
| Example 5 | | | | | | | |
| Comparative | 600 | 98 | 280 | 80 | 110 | 2.5 | 40 |
| Example 6 | | | | | | | |
| Comparative | 400 | 90 | 280 | 60 | 140 | 3.2 | 38 |
| Example 7 | | | | | | | |

Referring to Table 3, the positive photosensitive resin compositions according to Example 1 to 8 included a dissolution-controlling agent having a particular structure and a cross-linking agent having a particular structure in a particular ratio and exhibited improved sensitivity, film residue ratio, heat resistance, and mechanical properties.

By way of summation and review, in view of environmental concerns raised by the use of organic solvents, heat resistant photosensitive resin materials with an aqueous alkali solution have been considered.

For example, a method may include using a photosensitive resin composition that includes a mixture of a hydroxypolyamide resin (soluble in an alkali aqueous solution) and a photoacid generator such as a naphthoquinone diazide compound, which is a heat resistant resin after heat curing.

The mechanism for using the photosensitive resin composition may include exposing the photosensitive diazoquinone compound to a naphthoquinone diazide compound (i.e., a photosensitive diazoquinone compound) and a polybenzoxazole (PBO) precursor in a non-exposed portion, and transforming the photosensitive diazoquinone compound into an indene carboxylic acid compound to increase a dissolution rate in an alkaline aqueous solution. It is possible to manufacture a relief pattern composed of a non-exposed portion using a difference in a dissolution rate between an exposed portion and a non-exposed portion.

The photosensitive resin composition may form a positive relief pattern by exposure and development with an alkaline aqueous solution. In addition, thermally cured film characteristics may be obtained by heating.

In the manufacturing process of semiconductors and the like, a fine processing may be performed and an interval between patterns may be shorter. For example, when a layer decrease becomes large during development, in the non-exposed portion adjacent to the exposed portion of the opening, a dissolution rate of the non-exposed portion may be small, and a developing solution may contact a side as well as an upper side of the layer during development.

For example, a shape of the pattern could be excessively thin, deteriorating reliability of a semiconductor package in a manufacturing process of a semiconductor device. For example, a development almost without dissolving it (e.g., a development film residue ratio) may be performed. When the development film residue ratio is increased, a high exposure dose may be used for the phenomenon of the exposed portion (e.g., low sensitivity).

Phenolic compounds may be used as a heat resistant resin precursor to help increase a film residue ratio (developability control) and sensitivity in development. Some phenolic compounds may have limitations in improving flexibility, and it may be difficult to use them as circuit protective layers in electronic devices such as semiconductors, which are important in terms of elongation and elasticity, and the like.

One or more embodiments may provide a photosensitive resin composition capable of improving mechanical properties while simultaneously maintaining sufficient heat resistance.

The photosensitive resin composition according to an embodiment may help improve mechanical properties as well as heat resistance by including the cross-linking agent and the dissolution controlling agent having specific structures in a specific ratio, and may be used for manufacturing a circuit protective layer in electronic devices such as semiconductor devices.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A positive photosensitive resin composition, comprising:
an alkali soluble resin;
a photosensitive diazoquinone compound;
a dissolution controlling agent represented by Chemical Formula 1;
a cross-linking agent represented by Chemical Formula 2; and
a solvent,
wherein the dissolution controlling agent and the cross-linking agent are included in a weight ratio of about 1:1 to about 1:2: 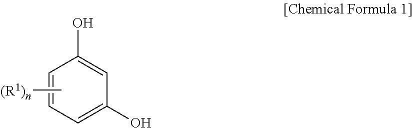
wherein in Chemical Formula 1,
R¹ is a substituted or unsubstituted C1 to C20 alkyl group, and
n is an integer of 0 or 1, 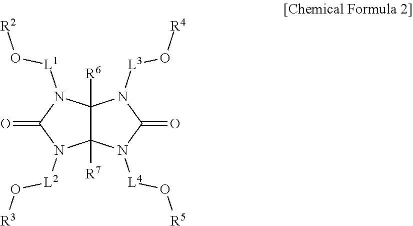
wherein in Chemical Formula 2,
R² to R⁷ are each independently a hydrogen atom or a substituted or unsubstituted C1 to C20 alkyl group, and
L¹ to L⁴ are each independently a substituted or unsubstituted C1 to C20 alkylene group.

2. The positive photosensitive resin composition as claimed in claim 1, wherein the dissolution controlling agent represented by Chemical Formula 1 is represented by Chemical Formula 1-1 or Chemical Formula 1-2: 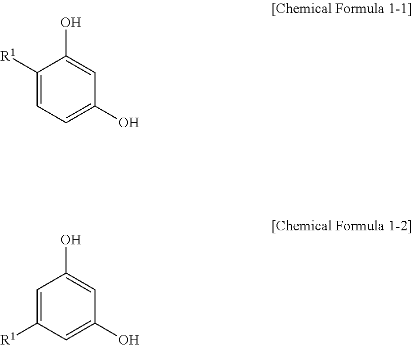
wherein, in Chemical Formula 1-1 and Chemical Formula 1-2, R¹ is a substituted or unsubstituted C1 to C20 alkyl group.

3. The positive photosensitive resin composition as claimed in claim 2, wherein R¹ is an unsubstituted C1 to C6 alkyl group.

4. The positive photosensitive resin composition as claimed in claim 1, wherein the dissolution controlling agent represented by Chemical Formula 1 is represented by one of Chemical Formula 1A to Chemical Formula 1E:

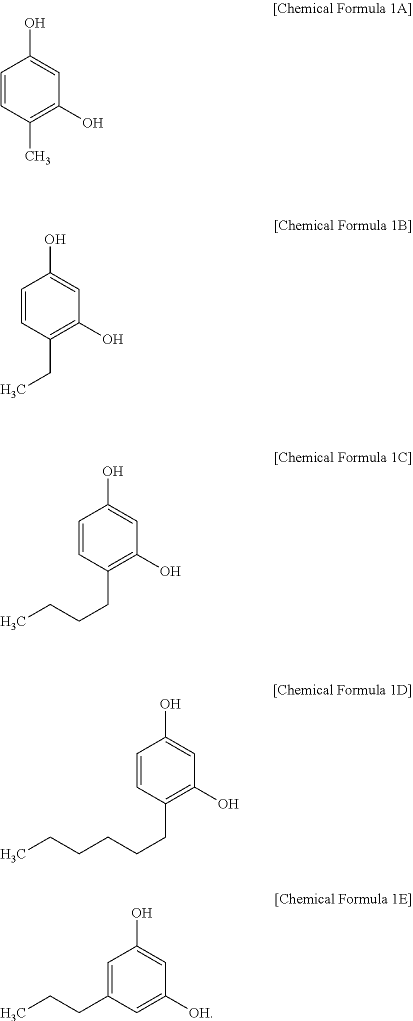

5. The positive photosensitive resin composition as claimed in claim 1, wherein, in Chemical Formula 2,
R² to R⁵ are each independently a substituted or unsubstituted C1 to C20 alkyl group, and
R⁶ and R⁷ are each a hydrogen atom.

6. The positive photosensitive resin composition as claimed in claim 1, wherein the alkali soluble resin includes a polybenzoxazole precursor, a polyimide precursor, a novolac resin, or a combination thereof.

7. The positive photosensitive resin composition as claimed in claim 1, wherein the photosensitive resin composition includes, based on 100 parts by weight of the alkali soluble resin:
about 1 part by weight to about 100 parts by weight of the photosensitive diazoquinone compound,
about 10 parts by weight to about 30 parts by weight of the dissolution controlling agent,
about 10 parts by weight to about 60 parts by weight of the cross-linking agent, and
about 100 parts by weight to about 500 parts by weight by weight of the solvent.

8. The positive photosensitive resin composition as claimed in claim 1, further comprising a diacid, an alkanol amine, a leveling agent, a silane coupling agent, a surfactant, an epoxy compound, a radical polymerization initiator, a thermal latent acid generator, or a combination thereof.

9. A photosensitive resin layer formed from the photosensitive resin composition as claimed in claim 1.

10. An electronic device comprising the photosensitive resin layer as claimed in claim 9.
